(19) United States
(12) Patent Application Publication
(10) Pub. No.: US 2010/0240194 A1
(43) Pub. Date: Sep. 23, 2010

(54) Method of fabricating semiconductor device

(76) Inventors: DeokYoung Jung, Seoul (KR); Ju-Seon Goo, Suwon-si (KR); Kyung-Mun Byun, Seoul (KR); Eunkee Hong, Seongnam-si (KR); Jun-Won Lee, Anyang-si (KR)

Correspondence Address: LEE & MORSE, P.C., 3141 FAIRVIEW PARK DRIVE, SUITE 500, FALLS CHURCH, VA, 22042, US

(21) Appl. No.: 12/659,841

(22) Filed: Mar. 23, 2010

(30) Foreign Application Priority Data
Mar. 23, 2009 (KR) 10-2009-0024597

(51) Int. Cl. H01L 21/762

(52) U.S. Cl. 438/437; 257/E21.546

(57) ABSTRACT

A method of fabricating a semiconductor device, the method including sequentially forming a pad oxide layer and a nitride layer on a substrate; etching the nitride layer, the pad oxide layer, and the substrate to form a trench; forming a sidewall oxide layer on a sidewall and a bottom of the trench; forming a oxide layer liner including nitrogen on the sidewall oxide layer; and forming a gap fill layer on the oxide layer liner

### BACKGROUND

1. Technical Field

Embodiments relate to a method of fabricating a semiconductor device.

2. Description of the Related Art

A STI (Shallow Trench Isolation) process is widely used as a device isolation technique for high density semiconductor devices. During the STI process, in order to prevent defects and to stabilize device characteristics, an oxide layer and a nitride layer liner may be sequentially formed on side walls and a bottom of an STI trench. Then, STI may be completed by filling in the trench with a high density plasma (HDP) oxide layer.

As a design rule of semiconductor devices is decreased, an aspect ratio of STI may be increased and an inner gap space of an STI trench may be decreased due to the presence of the liner.

### SUMMARY

Embodiments are directed to a method of fabricating a semiconductor device, which represents advances over the related art.

It is a feature of an embodiment to provide a method of fabricating a semiconductor device including forming a gap fill layer with improved layer quality in the semiconductor device.

It is another feature of an embodiment to provide a method of fabricating a semiconductor device that allows for annealing at a relatively low temperature.

At least one of the above and other features and advantages may be realized by providing a method of fabricating a semiconductor device, the method including sequentially forming a pad oxide layer and a nitride layer on a substrate; etching the nitride layer, the pad oxide layer, and the substrate to form a trench; forming a sidewall oxide layer on a sidewall and a bottom of the trench; forming a oxide layer liner including nitrogen on the sidewall oxide layer; and forming a gap fill layer on the oxide layer liner.

A nitrogen concentration of the oxide layer liner may be about 1 atom % to about 15 atom %.

The method may further include forming a nitride layer between the sidewall oxide layer and the oxide layer liner.

A thickness of the nitride layer may be about 200 Å or less.

The gap fill layer may be an oxide layer including Si—H or Si—OH bonding.

The gap fill layer may include at least one of a polysilazane, a siloxane, and a silicate compound.

The gap fill layer may include at least one of an HDP (High Density Plasma) layer, a FOX (Flowable OXide) layer, a TOSZ (Tonen SilaZene) layer, a SOG (Spin On Glass) layer, an USG (Undoped Silica Glass) layer, a TEOS (tetraethyl ortho silicate) layer, and an LTO (Low Temperature Oxide) layer.

Forming the oxide layer liner may be carried out by atomic layer deposition.

Forming the oxide layer liner may include providing a first source gas including at least one of SiH₄, Si₂H₆, Si₃H₈, SiH₂Cl₂, SiCl₄, Si₂Cl₆, and BTBAS, injecting a first purge gas to remove the first gas, injecting a second source gas including at least one of O₂, O₃, H₂O, NO, and N₂O, and injecting a second purge gas to remove the second gas.

The method may further include annealing at a temperature of about 300° C. to about 1,000° C. under an atmosphere including at least one of H₂O, O₂, N₂, and NH₃ gas after forming the gap fill layer.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 through 7 illustrate sectional views of stages in a method of fabricating a semiconductor device according to an embodiment;

FIG. 8 illustrates a sectional view of a semiconductor device fabricated according to another embodiment;

FIG. 9 illustrates a graph showing a relationship between depth and width of wet tolerance characteristics of a semiconductor device fabricated according to a comparative method and a semiconductor device fabricated according to an embodiment; and

FIG. 10 illustrates exemplary SEM images of a semiconductor device that correspond A, B, C, and D regions in FIG. 9.

### DETAILED DESCRIPTION

Korean Patent Application No. 10-2009-0024597, filed on Mar. 23, 2009, in the Korean Intellectual Property Office, and entitled: “Method of Fabricating Semiconductor Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

Advantages and features of the embodiments and methods of accomplishing the same may be understood more readily by reference to the following detailed description of preferred embodiments and the accompanying drawings. The embodiments may, however, be embodied in many different forms and should not be construed as being limited to the embodiments set forth herein. Rather, these embodiments are provided so that this disclosure will be thorough and complete and will fully convey the concept to those skilled in the art, and the embodiments will only be defined by the appended claims.

As used herein, the term “and/or” includes any and all combinations of one or more of the associated listed items.

It will be understood that the spatially relative terms are intended to encompass different orientations of the device in use or operation in addition to the orientation depicted in the figures.

Embodiments described herein will be described referring to plan views and/or cross-sectional views by way of ideal schematic views of the embodiments. Accordingly, the exemplary views may be modified depending on manufacturing technologies and/or tolerances. The embodiments are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the embodiments.

Hereinafter, by referring to the attached drawings, exemplary embodiments are described in detail.

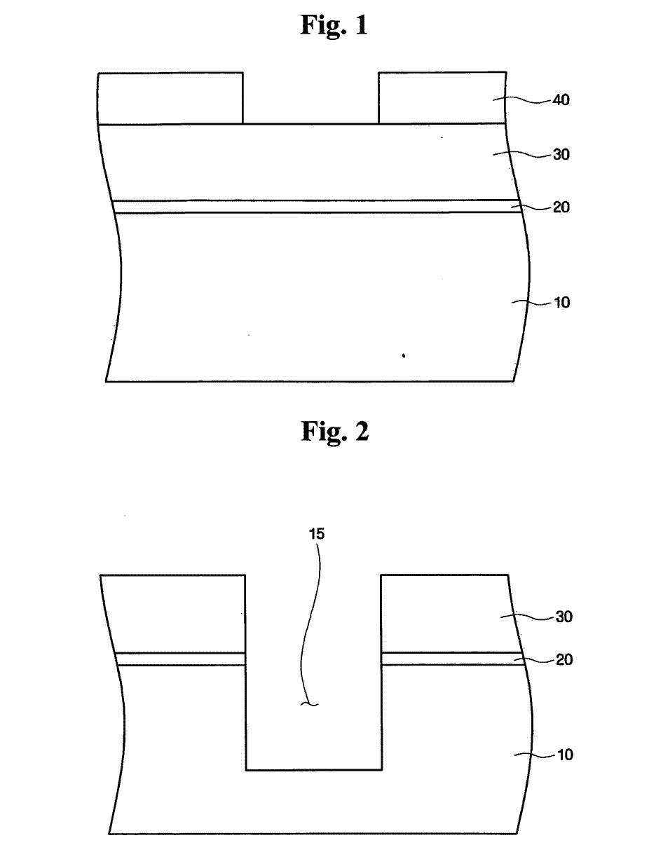

FIGS. 1 through 7 illustrate sectional views of stages in a method of fabricating a semiconductor device according to an embodiment.

First, referring to FIG. 1, a pad oxide layer 20 and a pad nitride layer 30 may be sequentially formed on a substrate 10. In an implementation, the substrate 10 may include, e.g., a silicon substrate. Next, an organic ARC (Anti Reflection Coating) (not illustrated) and a photo resist pattern 40 may be formed on the pad nitride layer 30. In this step, the photo resist pattern 40 may define an active region.

The pad oxide layer 20 may, e.g., reduce stress between the substrate 10 and the pad nitride layer 30. In an implementation, the pad oxide layer 20 may have a thickness of about 20 Å to about 200 Å.

The pad nitride layer 30 may be used as a hard mask during an etch process to form a trench region. The pad nitride layer 30 may be formed by, e.g., vapor-depositing silicon nitride to a thickness of about 500 Å to about 2,000 Å. The vapor deposition method may include, e.g., CVD (Chemical Vapor Deposition), SACVD (Sub-Atmospheric CVD), LPCVD (Low Pressure CVD), and/or PECVD (Plasma Enhanced CVD).

Referring to FIG. 2, using the photo resist pattern 40 as a mask, the pad nitride layer 30 and the pad oxide layer 20 may be etched using a dry etch process to form a trench.

When etching the pad nitride layer 30 a fluorocarbon series gas may be used. The fluorocarbon series gas may include, e.g., a CₓF_{y} series gas and/or a CₐH_{b}F_{c} series gas such as CF₄, CHF₃, C₂F₆, C₄F₈, CH₂F₂, CH₃F, CH₄, C₂H₂, C4F₆, and/or mixtures thereof. This step may be performed under, e.g., an Ar gas atmosphere.

Then, the photo resist pattern 40 may be removed. The photo resist pattern 40 may be removed by any suitable method, e.g., oxygen plasma ashing followed by organic strip.

Next, by using the pad nitride layer 30 and the pad oxide layer 20 as a mask, exposed portions of the substrate 10 may be anisotropically dry-etched to form a STI trench 15. The STI trench may constrain the active region.

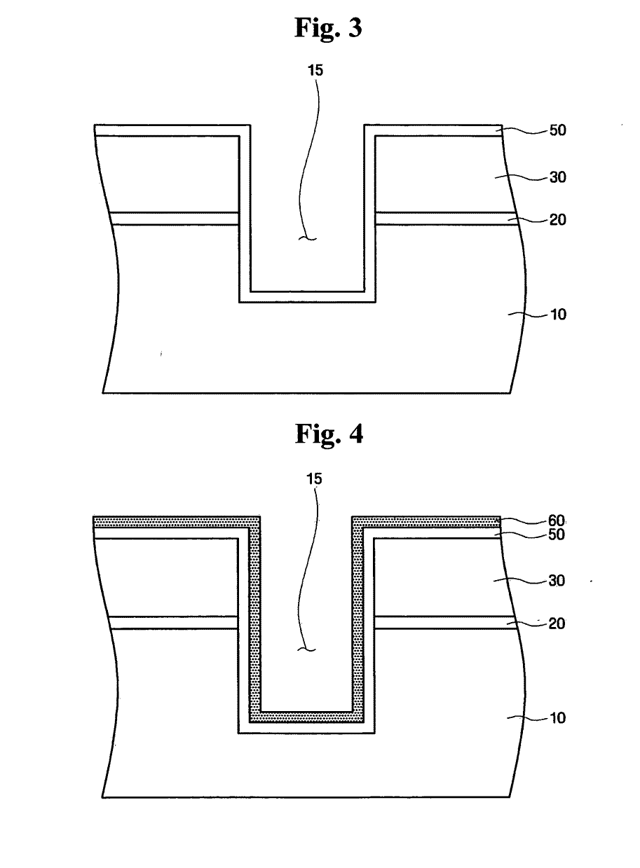

Referring to FIG. 3, a sidewall oxide layer 50 may be formed on the substrate 10 along sidewalls and a bottom of the trench 15. The sidewall oxide layer 50 may cure any silicon lattice defects and damage that may occur during the dry etch process to form the STI trench 15. The sidewall oxide layer 50 may also round corners of the STI trench 15 to prevent stress concentration at the corners. The sidewall oxide layer 50 may include, e.g., a thermal oxide layer, a CVD oxide layer, and/or an ALD (atomic layer deposition) layer.

Referring to FIG. 4, a nitride layer liner 60 may be formed on the substrate 10 along the sidewalls and bottom of the STI trench 15 on the sidewall oxide layer 50. The nitride layer liner 60 may include, e.g., a nitride layer or an oxynitride layer.

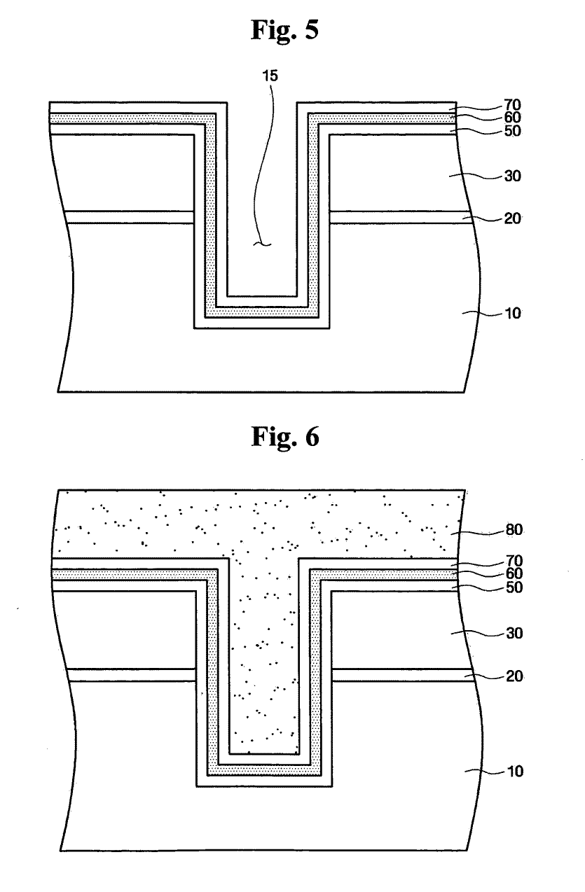

The nitride layer liner 60 may relieve stress generated due to differences in thermal expansion coefficients between the substrate 10 and an oxide layer liner (see 70 of FIG. 5) to be filled into the STI trench 15. The nitride layer liner 60 may thereby prevent defects generated in the active region from being transferred to the STI. Also, it may prevent further oxidizing of portions of the semiconductor substrate 10 adjacent to the STI due to oxygen diffusion into the semiconductor substrate 10 of an active region through STI during a subsequent heat treatment process or oxidation process, and it may prevent ions injected into the active region from diffusing out to the STI. The nitride layer liner 60 may have a thickness of about 200 Å or less.

Referring to FIG. 5, an oxide layer liner 70 including nitrogen may be formed on the nitride layer liner 60. The oxide layer liner 70 may have a nitrogen concentration of about 1 atom % to about 15 atom %.

Maintaining the nitrogen concentration of the oxide layer liner 70 at about 15 atom % or less may help ensure that a density of a gap fill layer (see 80 in FIG. 6) formed in a follow-up process is increased and over-etch of the gap fill layer 80 during wet etch and cleaning processes is prevented. Maintaining the nitrogen concentration of the oxide layer liner 70 at about 1 atom % or greater may help ensure that an annealing process may be performed at a low temperature and that occurrence of oxidative defects may be reduced. In an implementation, the oxide layer liner 70 may be formed by atomic layer deposition.

In more detail, referring to FIG. 4, the substrate 10 having the nitride layer liner 60 thereon may be loaded in a chamber and a first source gas may be provided. The first source gas may include, e.g., a silicon-containing gas. In an implementation, the first source gas may include, e.g., SiH₄, Si₂H₆, Si₃H₈, SiH₂Cl₂, SiCl₄, Si₂Cl₆, BTBAS (bis(tertiary-butylamino)silane), and/or combinations thereof.

The first source gas may be adsorbed on the nitride layer liner 60 and may form a thin silicon-containing atomic layer. In this step, in addition to the first source gas, an inert gas may be provided. The inert gas may include, e.g., Ar, He, Kr, Xe, and/or combinations thereof.

Next, portions of the first source gas not adsorbed on the nitride layer liner 60 and/or unreacted portions of the first source gas may be removed. To remove the first source gas, a first purge gas may be injected into the chamber. The first purge gas may include, e.g., an inert gas.

Then, a second source gas may be injected into the chamber. To form the oxide layer liner 70 including nitrogen, e.g., NO or N₂O, may be used as the second source gas.

After injecting the second source gas, plasma may be generated inside the chamber. The second source gas may be plasmarized to form a nitrogen-containing atomic layer and an oxygen-containing atomic layer on the silicon containing atomic layer.

Next, the second source gas may be removed by injecting a second purge gas. Similar to the first purge gas, the second purge gas may include, e.g., an inert gas.

By performing the first source gas injection, the first purge gas injection, the second source gas injection, and the second purge gas injection processes repeatedly, an oxide layer liner 70 having a desired thickness may be formed.

Referring to FIG. 6, the gap fill layer 80 may then be formed on the oxide layer liner 70. The gap fill layer 80 may include, e.g., a HDP (High Density Plasma) layer, a FOX (Flowable OXide) layer, a TOSZ (Tonen SilaZene) layer, a SOG (Spin On Glass) layer, an USG (Undoped Silica Glass) layer, a TEOS (tetraethyl ortho silicate) layer, a LTO (Low Temperature Oxide) layer, a silicate layer, a siloxane layer, a MSQ (Methyl SilseQuioxane) layer, a HSQ (Hydrogen SilseQuioxane) layer, and/or a polysilazane layer.

In an implementation, since an aspect ratio of the STI trench 15 may be increased and a gap fill margin reduced, a SOG layer formed by a spin-on method may be used as the gap fill layer 80. Such a gap fill layer 80 may be formed with an oxide layer including a Si—H or a Si—OH bond.

For example, a SOG solution may be spread on the oxide layer liner 70 using a spin coating method. Spreading the SOG solution may be performed by a spin coating method that uses, e.g., silicate, siloxane, MSQ (Methyl SilseQuioxane), HSQ (Hydrogen SilseQuioxane), and/or polysilazane series materials.

When performing heat treatment on the SOG solution, solvent components may be removed and the SOG solution may be hardened. As a result, the gap fill layer 80 may be formed with a SOG layer. For example, polysilazane may be a Si—N compound series inorganic polymer that does not include carbon. In an implementation, polysilazane may have, e.g., a —(SiH₂—NH)N— structure.

When polysilazane spreads, solvent components may be removed by baking. A pre-bake step at a temperature of about 80° C. to about 350° C. and a hard bake step at a temperature of about 400° C. may be performed. Pre-baking may facilitate removal of solvent components. Hard baking may facilitate discharge of gas from inside the gap fill layer 80, and defects of the gap fill layer 80 may be effectively cured.

Polysilazane may react with O₂ or H₂O, may be hardened at room temperature; and a fine high-purity silica layer may be formed by annealing. For example, annealing may be performed under an atmosphere including, e.g., H₂O, O₂, N₂, and/or NH₃ gas, at a temperature of about 300° C. to about 1,000° C.

The gap fill layer 80 may be formed as a silicon oxide layer through the annealing process. Since the annealing may be performed under a, e.g., H₂O, O₂, N₂, and/or NH₃ gas atmosphere, organic components and other components except silicon may be removed and oxygen may be introduced to form the silicon oxide layer.

In particular, oxygen may be discharged from the oxide layer liner 70 including nitrogen and may move to the gap fill layer 80. Thus, the oxide layer liner 70 may provide oxygen and thus the gap fill layer 80 may be formed as the silicon oxide layer.

Typically, when performing annealing under, e.g., H₂O, O₂, N₂, and/or NH₃ gas, it may be difficult to provide a region adjacent to the sidewalls and the bottom of the STI trench 15 with oxygen and thus the silicon oxide layer may not be formed uniformly. However, in the method according to an embodiment, the oxide layer liner 70 may provide oxygen to portions of the gap fill layer 80 adjacent to the sidewalls and may allow the gap fill layer 80 to be formed as the uniform silicon oxide layer. Also, since a density of the gap fill layer 80 may be increased, loss of the gap fill layer 80 due to etchant or cleaning solution during a subsequent wet etch or cleaning processes may be prevented.

Also, maintaining the nitrogen concentration of the oxide layer liner 70 within the above described amounts may help ensure that oxide layer liner 70 is hardened and, as a result, a shape of the STI trench 15 may be stably maintained even though a volume of the gap fill layer 80 may expand during an oxidation process.

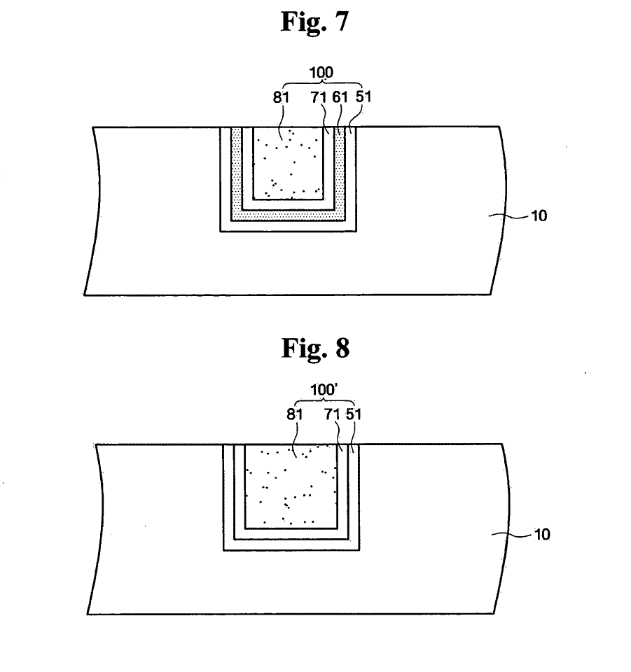

Finally, as illustrated in FIG. 7, a STI 100 is completed.

First, the gap fill layer 80 may be planarized to a same level as a surface of the pad nitride layer 30. Planarization may be performed by using, e.g., CMP (Chemical Mechanical Polishing) or etch back. In the planarization process, the pad nitride layer 30 may be used as a planarization stop layer. For example, when CMP is used to planarize the gap fill layer 80, the pad nitride layer 30 may function as a CMP stopper. It may be desirable to select a CMP slurry that etches the gap fill layer 80 faster than the pad nitride layer 30. In an implementation, a slurry that contains, e.g., a ceria series abradant, may be used.

Next, by removing the pad nitride layer 30 and the pad oxide layer 20, the STI 100 may be completed. The pad nitride layer 30 may be removed by, e.g., applying phosphoric acid; and the pad oxide layer 20 may be removed by using, e.g., dilute HF or BOE (Buffered Oxide Etchant), which is a mixture of NH₄F, HF, and deionized water.

The STI 100 may include a sidewall oxide layer 51, a nitride layer liner 61, an oxide layer liner 71 including nitrogen, and a gap fill layer 81. The method of fabricating semiconductor devices according to an embodiment may be applied to not only fabrication of the STI 100, but also to all dielectric layer processes including, e.g., a NAND STI and a DRAM ILD.

By using suitable fabrication processes, in an active region defined by the STI 100, a semiconductor device may be completed by performing addition steps including, e.g., a step that forms active devices such as a transistor and passive devices such as a capacitor, a step that forms interconnects to provide active and passive devices with electrical inputs and outputs, a step that forms a passivation layer on the substrate, and a step that packages the substrate. Such subsequent processes are roughly described to avoid ambiguous interpretation of the embodiments.

FIG. 8 illustrates a sectional view of a semiconductor device fabricated according to another embodiment.

In the method of fabricating a semiconductor device according to the present embodiment, a sidewall oxide layer 51 may be formed on a substrate 10. Then, an oxide layer liner 71 including nitrogen may be formed directly on the sidewall layer 51. Thus, by omitting the nitride layer liner between the sidewall oxide layer 51 and the oxide layer liner 71 and forming only the oxide layer liner 71 including nitrogen, a STI 100′ may be formed.

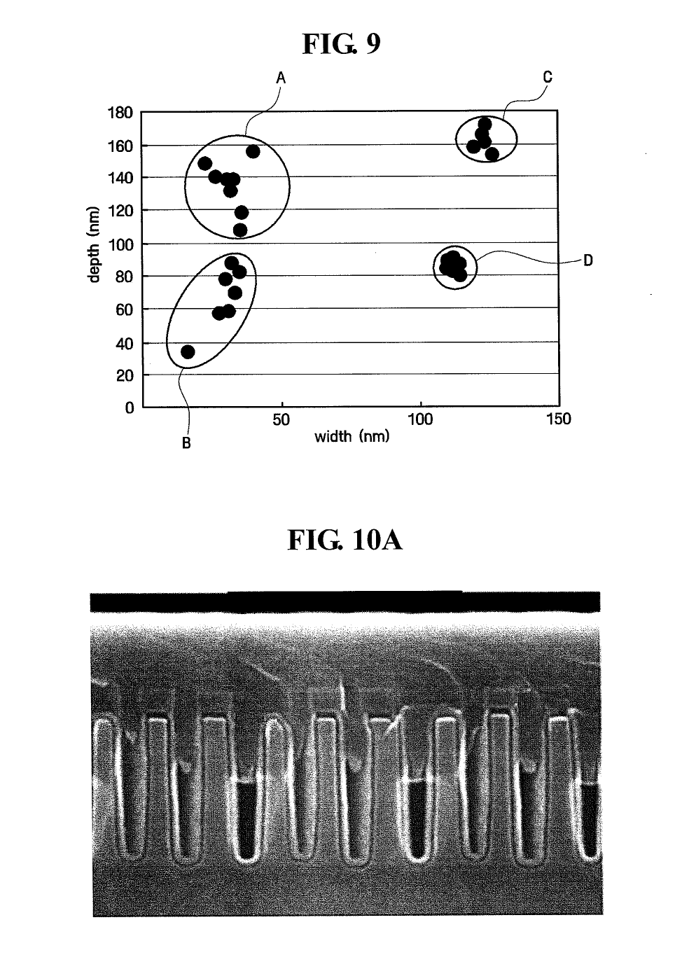

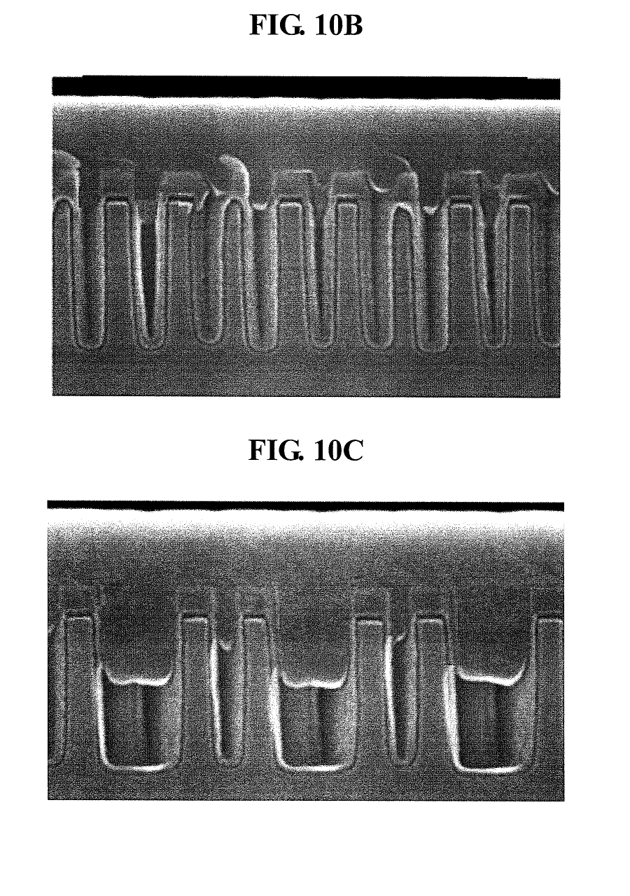

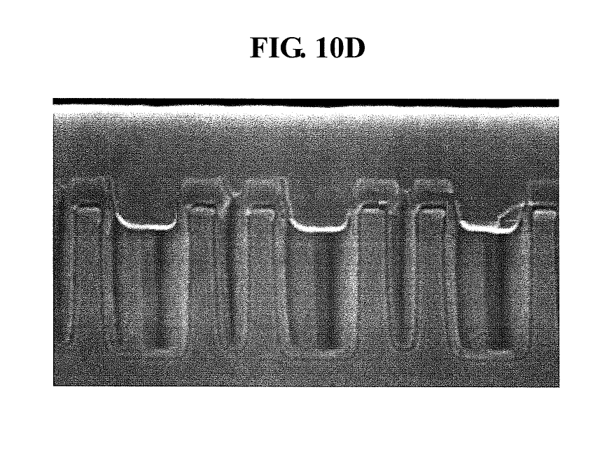

Referring to FIGS. 9 and 10, wet tolerance characteristics of a semiconductor device fabricated according to an embodiment will be described.

FIG. 9 illustrates a graph showing a relationship between depth and width that represents wet tolerance characteristics of a semiconductor device fabricated according to a comparative method and a semiconductor device fabricated according to an embodiment. FIG. 10 illustrates exemplary SEM images of a semiconductor device that correspond to A, B, C, and D regions in FIG. 9.

First, in FIG. 9 the horizontal axis represents a width of a STI and the vertical axis represents a depth of the STI.

(A) and (C) in FIG. 10 illustrate SEM images after cleaning the STI including an oxide layer liner formed by a SOG method. (B) and (D) illustrate SEM images after cleaning STI including an oxide layer liner including nitrogen formed by a SOG method.

Referring to FIGS. 9 and 10, it may be seen that the oxide layer liners of (A) and (C) were etched deeper than the oxide layer liners of (B) and (D).

Also, it may be seen that in (C) and (D), having a wider STI width, the gap fill layer was etched to a greater degree when compared to (A) and (B). However, it may be seen that an etch depth difference depending on the STI width was insignificant; and an amount of etch of the gap fill layer was reduced significantly when the oxide layer liner contained nitrogen.

Since a semiconductor device may shrink during STI formation, forming an oxide layer and a nitride layer liner followed by an STI gap fill process may become difficult due to insufficient space. Accordingly, widths of the oxide layer and the nitride layer liner may be reduced. However, when simply reducing the widths of the oxide layer and the nitride layer liner, reliability of a semiconductor device may decrease and it may become difficult to perform subsequent processes. Specifically, when the thickness of the nitride layer liner is reduced, oxidative defects may be increased during a subsequent annealing process performed at a high temperature under an oxidization atmosphere. Thus, the method of fabricating a semiconductor device according to an embodiment may help ensure excellent layer quality of the gap fill layer by, inter alia, allowing for annealing at a lower temperature.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a semiconductor device, the method comprising:
sequentially forming a pad oxide layer and a nitride layer on a substrate;
etching the nitride layer, the pad oxide layer, and the substrate to form a trench;
forming a sidewall oxide layer on a sidewall and a bottom of the trench;
forming a oxide layer liner including nitrogen on the sidewall oxide layer; and
forming a gap fill layer on the oxide layer liner.

2. The method as claimed in claim 1, wherein a nitrogen concentration of the oxide layer liner is about 1 atom % to about 15 atom %.

3. The method as claimed in claim 1, further comprising forming a nitride layer between the sidewall oxide layer and the oxide layer liner.

4. The method as claimed in claim 3, wherein a thickness of the nitride layer is about 200 Å or less.

5. The method as claimed in claim 1, wherein the gap fill layer is an oxide layer including Si—H or Si—OH bonding.

6. The method as claimed in claim 5, wherein the gap fill layer includes at least one of a polysilazane, a siloxane, and a silicate compound.

7. The method as claimed in claim 1, wherein the gap fill layer includes at least one of an HDP (High Density Plasma) layer, a FOX (Flowable OXide) layer, a TOSZ (Tonen SilaZene) layer, a SOG (Spin On Glass) layer, an USG (Undoped Silica Glass) layer, a TEOS (tetraethyl ortho silicate) layer, and an LTO (Low Temperature Oxide) layer.

8. The method as claimed in claim 1, wherein forming the oxide layer liner is carried out by atomic layer deposition.

9. The method as claimed in claim 8, wherein forming the oxide layer liner includes:
providing a first source gas including at least one of SiH₄, Si₂H₆, Si₃H₈, SiH₂Cl₂, SiCl₄, Si₂Cl₆, and BTBAS,
injecting a first purge gas to remove the first gas,
injecting a second source gas including at least one of O₂, O₃, H₂O, NO, and N₂O, and
injecting a second purge gas to remove the second gas.

10. The method as claimed in claim 1, further comprising annealing at a temperature of about 300° C. to about 1,000° C. under an atmosphere including at least one of H₂O, O₂, N₂, and NH₃ gas after forming the gap fill layer.
